(19) United States
(12) Patent Application Publication
(10) Pub. No.: US 2020/0221581 A1
(43) Pub. Date: Jul. 9, 2020

(54) REFLOW DEVICE OF REFLOW SOLDERING EQUIPMENT

(71) Applicant: Jetinn Global Equipment Ltd., Apia (WS)

(72) Inventors: Yu-Jung Wu, Zhubei (TW); Shu-Yu Hu, Taichung (TW)

(21) Appl. No.: 16/716,181

(22) Filed: Dec. 16, 2019

(30) Foreign Application Priority Data
Jan. 3, 2019 (TW) 108100239

(51) Int. Cl. H05K 3/34; B23K 1/005

(52) U.S. Cl. CPC H05K 3/3494; B23K 1/005; H05K 3/3452

(57) ABSTRACT

Disclosed is a reflow device of a reflow soldering equipment, the reflow soldering equipment being provided with a reflowing zone, the reflow device comprising: a heating light source; a light mask having a plurality of holes, the light mask being irradiated by the heating light in such a manner that the heating light passes through the holes of the light mask to irradiate into the reflowing zone so as to form a plurality of irradiation areas; and a transporting member having a carrier which carries an object to be processed to move through the reflowing zone along a transporting path, wherein a plurality of predetermined areas to be reflowed are defined in an upper surface of the object to be processed, the carrier is configured to, when the object to be processed is in a position where the predetermined area to be reflowed is within the irradiation area respectively, halt at the position for a predetermined irradiation time, and then continue to move forward and move through the reflowing zone.

### CROSS-REFERENCE TO RELATED APPLICATION

This application claims priority to Taiwanese Patent Application No. TW 108100239 filed Jan. 3, 2019, entitled, “Reflow device for heating reflow equipment”, which is incorporated by reference herein in its entirety.

### FIELD OF THE INVENTION

The present invention relates to a reflow device used in a reflow soldering equipment, and more particularly relates to a reflow device that performs a reflow process on an object to be processed during the object to be process being in a still state.

### BACKGROUND OF THE INVENTION

Nowadays, with the evolution of electronic products, various mobile devices or wearable devices are being introduced and replacing traditional computers. To meet the demand for miniaturization of these electronic products, the requirement for smaller and more powerful chips is continuously growing. Surface-mount technology (SMT) is widely applied to mount the chips of these mobile devices or wearable devices to a substrate. In the surface-mount technology (SMT), the operation of reflow soldering is necessary. The reflow soldering operation is for soldering the chips on the substrate. Therefore, the reflow soldering is a very important process in the surface-mount technology.

In a conventional reflow soldering, an object to be processed is transported to a reflow soldering equipment by a conveyor belt and is subjected to a process of sequential four stages including preheating, thermal soaking, reflowing and cooling. The preheating is for volatilizing solvents existing in solders. The thermal soaking is for activating the fluxes to remove oxides and evaporate excess water. The reflowing is for completely melting the solders existing between the chip and a contact pad. The cooling is for solidifying the melted solders.

Due to the space within a mobile device or a wearable device is limited, a substrate is usually designed with dense layout such that it causes the wiring layout to be complicated and leads the distance between the contact pads on the substrate becoming close. Therefore, when the substrate of such electronic product is being reflowed, it is easy to cause a problem that a solder bridge is formed between adjacent solders due to vibration. In addition, the conventional reflow soldering equipment is not easy to control the temperature during the reflow process such that the chip often tilts due to delayed melting of the solder. Moreover, when the chip is subjected to the reflow process, it is necessary to heat for a relatively long time to reach the temperature (about 217° C.) for completely melting the solder. As a result, during the reflow process, the substrate may be bent or deformed, thereby causing failure of the substrate.

### SUMMARY OF THE INVENTION

Accordingly, one objective of the present invention is to provide a reflow device of a reflow soldering equipment to avoid the problem of forming solder bridges between adjacent solders due to vibration during the reflow process. Moreover, the present invention could effectively concentrate heating light to improve the yield of the reflow soldering.

In order to overcome the technical problems in prior art, the present invention provides a reflow device of a reflow soldering equipment, the reflow soldering equipment being provided with a reflowing zone, the reflow device comprising: a heating light source provided as projecting heating light into the reflowing zone; a light mask disposed between the heating light source and the reflowing zone, the light mask having a plurality of holes, the light mask being irradiated by the heating light in such a manner that the heating light passes through the holes of the light mask to irradiate into the reflowing zone so as to form a plurality of irradiation areas; and a transporting member having a carrier which carries an object to be processed to move through the reflowing zone along a transporting path, wherein a plurality of predetermined areas to be reflowed are defined in an upper surface of the object to be processed, the carrier is configured to, when the object to be processed is in a position where the predetermined area to be reflowed is within the irradiation area respectively, halt at the position for a predetermined irradiation time, and then continue to move forward and move through the reflowing zone.

According to one embodiment of the present invention, a reflow device is provided, wherein a total area of the irradiation areas is not larger than an area of the predetermined areas to be reflowed.

According to one embodiment of the present invention, a reflow device is provided, wherein the light mask is disposed between the heating light source and the transporting member in a removable manner.

According to one embodiment of the present invention, a reflow device is provided, wherein the transporting member is a conveyor belt.

According to one embodiment of the present invention, a reflow device is provided, wherein the heating light source is a halogen lamp.

According to one embodiment of the present invention, a reflow device is provided, wherein the object to be processed is a substrate on which a chip is disposed, or the object to be processed is a plurality of chips which are stacked with each other.

By the technical means according to the present invention, when device with miniaturized and complicated layout is being reflowed, there will be no solder bridges forming between adjacent solders. Furthermore, by forming of the irradiation areas in which the heating light could be controlled as concentrating to the predetermined areas to be reflowed, the present invention is with merit that the time of the reflow soldering can be shortened, and the process efficiency of the reflow soldering equipment can be greatly improved.

### BRIEF DESCRIPTION OF THE DRAWINGS

The structure and the technical means adopted by the present invention to achieve the above and other objects can be best understood by referring to the following detailed description of the preferred embodiments and the accompanying drawings.

FIG. 1 is a schematic diagram illustrating a reflow soldering equipment according to one embodiment of the present invention;

FIG. 2 is a schematic diagram illustrating a reflow device of the reflow soldering equipment according to the embodiment of the present invention;

FIG. 3 is a schematic diagram illustrating the reflow device of the reflow soldering equipment according to the embodiment of the present invention when a substrate and a chip disposed thereon are reflowed; and

FIG. 4 is a schematic diagram illustrating the reflow device of the reflow soldering equipment according to the embodiment of the present invention when a plurality of chips which are stacked with each other are reflowed.

### DETAILED DESCRIPTION OF THE PREFERRED EMBODIMENTS

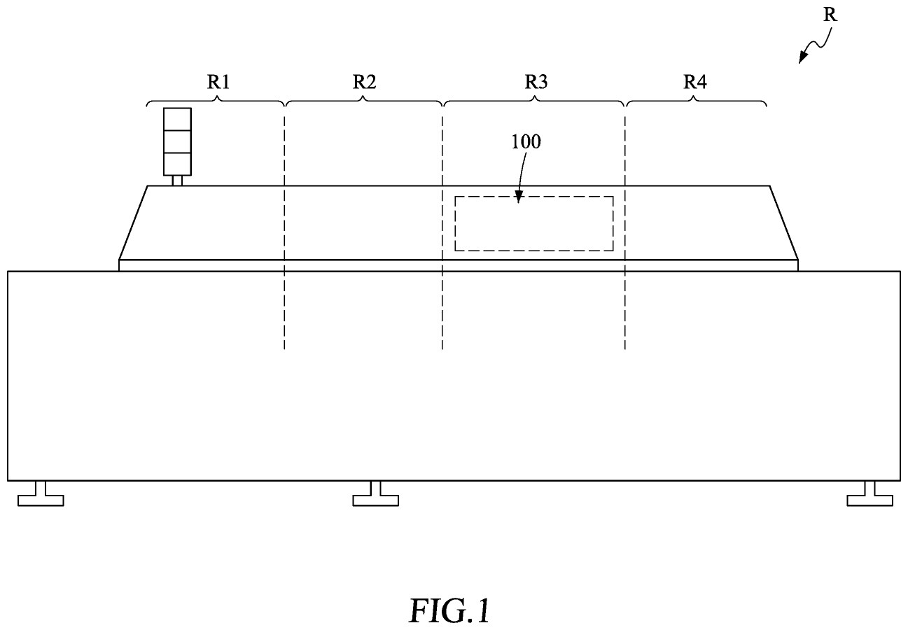

The preferred embodiments of the present invention are described in detail below with reference to FIG. 1 to FIG. 4. The description is used for explaining the embodiments of the present invention only, but not for limiting the scope of the claims.

As shown in FIG. 1, in one embodiment of the present invention, a reflow soldering equipment R is shown. As shown in FIG. 1, the reflow soldering equipment R is provided with a plurality of processing zones, including a preheating zone R1, a thermal soaking zone R2, a reflowing zone R3 and a cooling zone R4. A reflow device 100 is provided in a position corresponding to the reflowing zone R3 of the reflow soldering equipment R. The reflow device 100 comprises: a heating light source 1, which is provided to irradiate heating light into the reflowing zone R3. The reflow device 100 further comprises a light mask 2 disposed between the heating light source 1 and the reflowing zone R3. The light mask 2 has a plurality of holes 21 through which the heating light of the heating light source 1 passes through to irradiate into the reflowing zone R3 so as to form a plurality of irradiation areas L. The reflow device 100 further comprises a transporting member 3 which has a carrier 31. The carrier 31 moves through the reflowing zone R3 along a transporting path K while carrying an object to be processed W. An upper surface of the object to be processed W is provided with a plurality of predetermined areas to be reflowed. The carrier 31 is configured to, when the object to be processed W is in a position where the predetermined area to be reflowed is within the irradiation area L respectively, halt at the position for a predetermined irradiation time, and then continue to move forward and moves through the reflowing zone R3. In other words, the plurality of processing zones, including a preheating zone R1, a thermal soaking zone R2, a reflowing zone R3 and a cooling zone R4 are provided such that the object to be processed W when initially transported into the reflow soldering equipment R will be moved sequentially through the four zones, i.e., from the preheating zone R1 to the thermal soaking zone R2 to the reflowing zone R3 and to the cooling zone R4. Thereafter the object to be processed W is subjected to a complete reflow soldering of four stages including preheat, thermal soak, reflow and cooling. The reflow device 100 of the present invention is disposed in the reflowing zone R3.

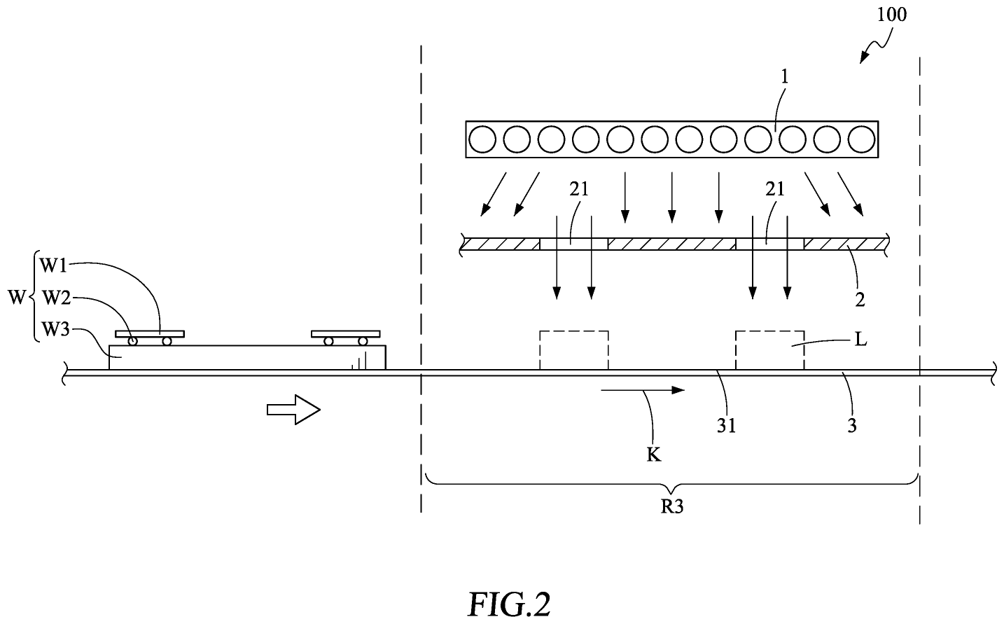

As shown in FIG. 2, in the embodiment, the reflow device 100 in the reflowing zone R3 includes the heating light source 1, the light mask 2 and the transporting member 3. The number of the holes 21 of the light mask 2 is determined according to the requirements of the reflow soldering for the object to be processed W. The small hole could be plural ones or a single one. The irradiation areas L, which is on the carrier 31 of the transporting member 3, are areas where the heating light passes through the holes 21 of the light mask 2. The reflow device 100 according to the present invention further includes a thermometer (not shown). The thermometer is disposed at the reflowing zone R3 to wirelessly measure the temperature of the irradiation areas L, and the measured temperature value is transmitted, as reference data for confirming the state of the reflow process, to the reflow soldering equipment R through a transmission line.

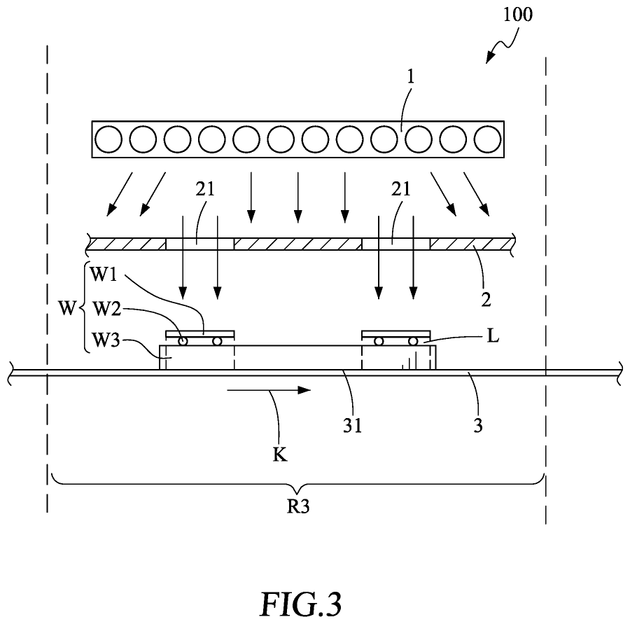

As shown in FIG. 3, the transporting member 3 is configured to transport the object to be processed W carried by the carrier 31 into the reflowing zone R3 along the transporting path K. The transporting member 3 is provided with a controller (not shown), which is configured to control the operation of the transporting member 3 based on the data, which is inputted in advance, regarding the opening 21 of the light mask 2 so as to transport and then halt the object to be processed W in a position where the predetermined area to be reflowed of the object to be processed W is accurately within the irradiation areas L. Furthermore, in accordance with the temperature value of the irradiation area L transmitted from the thermometer, a halting time that the object to be processed W is halted for reflowing the object to be processed W is calculated. Accordingly, since the whole chip W1 is stopped to receive the heating light of the heating light source 1 during the reflowing process, the solder W2 melts evenly such that the chip will not tilt. Furthermore, since the solder W2 is heated while in a still state, the problem of forming solder bridges between adjacent solders can be effectively avoided. After being reflowed, the object to be processed W carried by the carrier 31 will be continuously transported to move forward and move through the reflowing zone R3 along the transporting path K.

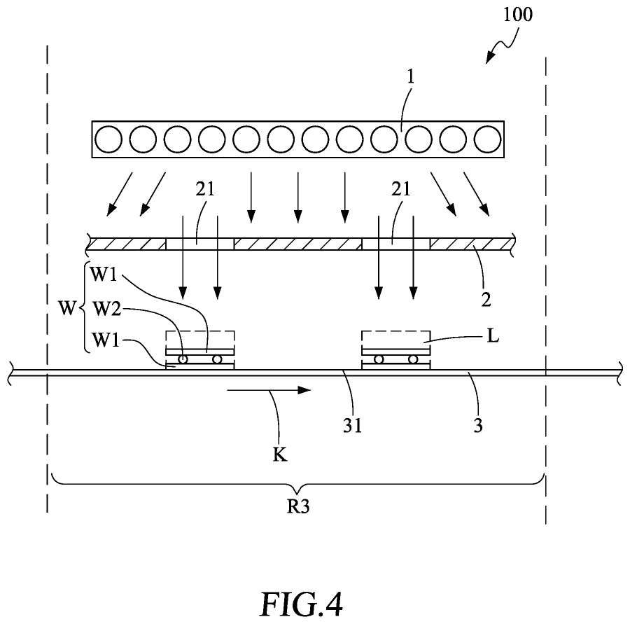

As shown in FIG. 4, the transporting member 3 transports the chips W1 stacked with each other and the solder W2 disposed between the chips W1 on the carrier 31 into the reflowing zone R3 along the transporting path K. The transporting member 3 is provided with a controller (not shown), which is configured to control the operation of the transporting member 3 based on the data, which is inputted in advance, regarding the opening 21 of the light mask 2 so as locate the chips W1, which are stacked with each other, and the solder W2, which is disposed between the chips W1, carried on the carrier 31, to a position where it is accurately corresponding to the irradiation area L. Further, in accordance with the temperature value of the irradiation area L transmitted from the thermometer, a halting time is calculated. The halting time is a time period that the object to be processed W is halted for reflowing the chips W1 stacked with each other and the solder W2 disposed between the chips W1, carried on the carrier 31. Accordingly, since the whole chip W1 is stopped to receive the heating light of the heating light source 1 during the reflowing process, the solder W2 melts evenly such that the chip will not tilt. Furthermore, since the solder W2 is heated while in a still state, the problem of forming solder bridges between adjacent solders can be effectively avoided. After being reflowed, the chips W1 stacked with each other and carried by the carrier 31 are continuously transported to move forward and move through the reflowing zone R3 along the transporting path K.

In the reflow device 100 of the reflow soldering equipment according to one embodiment of the present invention, a total area of the irradiation areas is not larger than an area of the areas to be reflowed. FIG. 3 illustrates the reflow process for a substrate W3 on which the chip W1 and the solder W2 are disposed. Since the areas of the substrate W3 other than the areas of the chip W1 and the solder W2 may be warped or deformed after being irradiated by the heating light in the irradiation area L, the size of the holes 21 of the light mask 2 in the present invention is calculated in consideration of the projection angle of the heating light to prevent the heating light of the irradiation area L from diffusing outward.

In the reflow device 100 of the reflow soldering equipment according to one embodiment of the present invention, the light mask 2 is disposed between the heating light source 1 and the transporting member 3 in a removable manner. In the present invention, a light mask replacement opening (not shown) is provided behind the reflowing zone R3 of the reflow soldering equipment R such that the light mask 2 could be conveniently replaced by different types of light mask based on the layout of the object to be processed W.

In the reflow device 100 of the reflow soldering equipment according to one embodiment of the present invention, the transporting member 3 is a conveyor belt. The object to be processed W is moved in the reflowing zone R3 by the conveyor belt. However, the present invention is not limited to this, the object to be processed W may be carried by a sliding carrier driven by a ball screw drive system so as to improve position alignment between the irradiation areas L and the predetermined areas to be reflowed.

In the reflow device 100 of the reflow soldering equipment according to one embodiment of the present invention, the heating light source 1 is a halogen lamp for providing stable thermal energy. However, the present invention is not limited to this, and other types of light sources may be used for heating as long as the solder W2 can be brought to the melting temperature.

In the reflow device 100 of the reflow soldering equipment according to one embodiment of the present invention, the object to be processed W is a substrate W3 on which a chip W1 is disposed (as shown in FIG. 3), or the object to be processed W is a plurality of chips W1 which are stacked with each other (as shown in FIG. 4). The reflow device 100 of the present invention can be applied to various kinds of objects to be processed. The present invention is with the characteristics of the irradiation area L and heating in a still state, by which a steady heating could be applied to any specific areas so as to achieve a good heating effect both on soldering of the chip W1 to the chip W1 and soldering of the chip W1 to the substrate W3.

Compared with a conventional reflow soldering equipment in which an object to be processed continues moving during the reflow process, the reflow device 100 of the reflow soldering equipment R of the present invention allows that the object to be processed W is being reflowed in a completely still state such that the solder W2 is with less positional displacement and short circuit of bridging caused by vibration. In addition, the irradiation areas L is provided to ensure that the area of the substrate W3 other than the areas to be reflowed is not irradiated by the heating light of the heating light source 1. It thus prevents the substrate W3 from being warped or deformed due to excessive heating. Furthermore, the light mask 2 is provided such that the heating light can be concentrated to shorten the time of the reflow soldering. Moreover, the present invention could greatly improve the process efficiency of the reflow soldering equipment.

The above description is only an explanation of the preferred embodiments of the present invention. One having ordinary skill in the art can make various modifications according to the above description and the claims defined below. However, those modifications shall still fall within the scope of the present invention.

What is claimed is:

1. A reflow device of a reflow soldering equipment, the reflow soldering equipment being provided with a reflowing zone, the reflow device comprising:
a heating light source provided as projecting heating light into the reflowing zone;
a light mask disposed between the heating light source and the reflowing zone, the light mask having a plurality of holes, the light mask being irradiated by the heating light in such a manner that the heating light passes through the holes of the light mask to irradiate into the reflowing zone so as to form a plurality of irradiation areas; and
a transporting member having a carrier which carries an object to be processed to move through the reflowing zone along a transporting path,
wherein a plurality of predetermined areas to be reflowed are defined in an upper surface of the object to be processed,
the carrier is configured to, when the object to be processed is in a position where the predetermined area to be reflowed is within the irradiation area respectively, halt at the position for a predetermined irradiation time, and then continue to move forward and move through the reflowing zone.

2. The reflow device as claimed in claim 1, wherein a total area of the irradiation areas is not larger than an area of the predetermined areas to be reflowed.

3. The reflow device as claimed in claim 1, wherein the light mask is disposed between the heating light source and the transporting member in a removable manner

4. The reflow device as claimed in claim 1, wherein the transporting member is a conveyor belt.

5. The reflow device as claimed in claim 1, wherein the heating light source is a halogen lamp.

6. The reflow device as claimed in claim 1, wherein the object to be processed is a substrate on which a chip is disposed, or the object to be processed is a plurality of chips which are stacked with each other.
